(19) United States
(12) Patent Application Publication
(10) Pub. No.: US 2025/0324641 A1
(43) Pub. Date: Oct. 16, 2025

(54) SEMICONDUCTOR DEVICE AND MANUFACTURING METHOD THEREOF

(71) Applicant: Hon Young Semiconductor Corporation, Hsinchu City (TW)

(72) Inventor: Yu-Tsu LEE, Hsinchu City (TW)

(21) Appl. No.: 18/739,353

(22) Filed: Jun. 11, 2024

(30) Foreign Application Priority Data
Apr. 16, 2024 (TW) 113114181

(51) Int. Cl. H01L 29/66; H01L 21/02; H01L 21/28; H01L 29/06; H01L 29/423; H01L 29/78

(52) U.S. Cl. CPC H10D 30/0297; H01L 21/02236; H01L 21/02255; H01L 21/28211; H10D 30/668; H10D 62/109; H10D 64/516

(57) ABSTRACT

A method of manufacturing a semiconductor device includes forming a shielding region, well region, and a source region in a drift layer, in which the source region is over the well region, a top of the shielding region is lower than a bottom of the well region, and at least a portion of the shielding region does not overlap the well region, forming a trench in the drift layer, the trench exposing the shielding region, forming a gate dielectric layer at a sidewall and a bottom of the trench, in which a thickness of the gate dielectric layer along the source region is greater than a thickness of the gate dielectric layer along the well region, and forming a gate in the trench.

### CROSS-REFERENCE TO RELATED APPLICATION

This application claims priority to Taiwan Application Serial Number 113114181, filed Apr. 16, 2024, which is herein incorporated by reference in its entirety.

### BACKGROUND

### Technical field

Some embodiments of the present disclosure relate to a semiconductor device and a manufacturing method thereof.

### Description of Related Art

To increase the channel density of a metal oxide semiconductor field effect transistor (MOSFET), the MOSFET may have a gate trench structure and a vertical channel to reduce the on-resistance of the MOSFET. However, there are still several issues to be solved when forming the MOSFET having the gate trench structure.

### SUMMARY

Some embodiments of the present disclosure provides a method of manufacturing a semiconductor device, including forming a shielding region, well region, and a source region in a drift layer, in which the source region is over the well region, a top of the shielding region is lower than a bottom of the well region, and at least a portion of the shielding region does not overlap the well region, forming a trench in the drift layer, the trench exposing the shielding region, forming a gate dielectric layer at a sidewall and a bottom of the trench, in which a thickness of the gate dielectric layer along the source region is greater than a thickness of the gate dielectric layer along the well region, and forming a gate in the trench.

In some embodiments of the present disclosure, the method further includes before forming the gate dielectric layer, performing a thermal oxidation process to the sidewall and the bottom of the trench to form a thermal oxidation layer at the sidewall and the bottom of the trench, in which a thickness of the thermal oxidation layer along the source region is greater than a thickness of the thermal oxidation layer along the well region, and removing the thermal oxidation layer.

In some embodiments of the present disclosure, a thickness of the thermal oxidation layer along the shielding region is greater than the thickness of the thermal oxidation layer along the well region.

In some embodiments of the present disclosure, the thermal oxidation process oxidizes a top of the source region slower than oxidizes a sidewall of the source region.

In some embodiments of the present disclosure, after removing the thermal oxidation layer, a top of the trench is wider than the bottom of the trench.

In some embodiments of the present disclosure, a portion of the gate dielectric layer is formed by performing a thermal oxidation process, and the thermal oxidation process oxidizes a top of the source region slower than oxidizes a sidewall of the source region.

In some embodiments of the present disclosure, a thickness of the gate dielectric layer along the shielding region is greater than a thickness of the gate dielectric layer along the well region.

In some embodiments of the present disclosure, a doping concentration of the source region is greater than a doping concentration of the well region.

In some embodiments of the present disclosure, a doping concentration of the shielding region is greater than a doping concentration of the well region.

In some embodiments of the present disclosure, a top of the gate is wider than the bottom of the gate.

Some embodiments of the present disclosure provides a semiconductor device including a drift layer, a gate over the drift layer, a gate dielectric layer along a sidewall and a bottom of the gate, a shielding region at a bottom of the gate dielectric layer, a well region at a side of the gate dielectric layer, and a source region at the side of the gate dielectric layer and over the well region, in which a thickness of the gate dielectric layer along the source region is greater than a thickness of the gate dielectric layer along the well region.

In some embodiments of the present disclosure, a thickness of the gate dielectric layer along the shielding region is greater than the thickness of the gate dielectric layer along the well region.

In some embodiments of the present disclosure, a doping concentration of the shielding region is greater than a doping concentration of the well region.

In some embodiments of the present disclosure, the gate dielectric layer along the source region has a curved sidewall.

In some embodiments of the present disclosure, a top of the gate is wider than the bottom of the gate.

In some embodiments of the present disclosure, a doping concentration of the source region is greater than a doping concentration of the well region.

In some embodiments of the present disclosure, a conductivity type of the source region is different from a conductivity type of the well region.

In some embodiments of the present disclosure, a bottom of the source region is wider than the top of the source region.

In some embodiments of the present disclosure, the gate dielectric layer is in contact with the drift layer, and the thickness of the gate dielectric layer along the source region is greater than a thickness of the gate dielectric layer along the drift layer.

In some embodiments of the present disclosure, a doping concentration of the source region is greater than a doping concentration of the drift layer.

### BRIEF DESCRIPTION OF THE DRAWINGS

FIGS. 1-6 illustrate cross-sectional views of forming a semiconductor device in some embodiments of the present disclosure.

### DETAILED DESCRIPTION

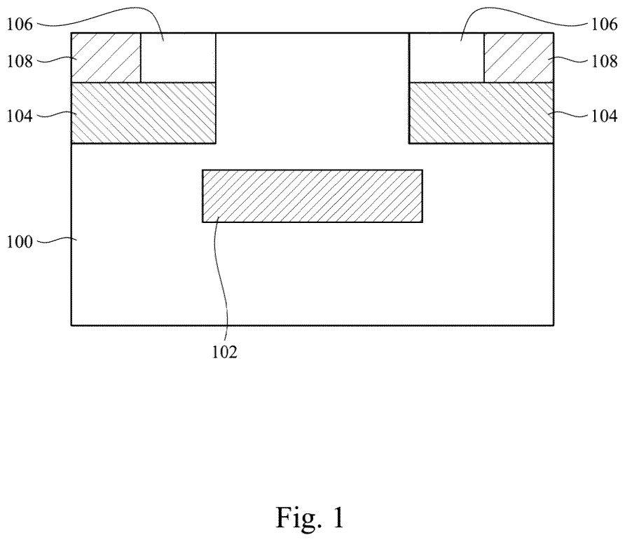

FIGS. 1-6 illustrate cross-sectional views of forming a semiconductor device in some embodiments of the present disclosure. Referring to FIG. 1, a shielding region 102, well regions 104, source regions 106, and body contact regions 108 are formed in the drift layer 100, in which the source regions 106 and the body contact regions 108 are over the well regions 104, the top of the shielding region 102 is lower than the bottom of the well regions 104, and at least a portion of the shielding region 102 does not overlap the well regions 104. In some embodiments, the drift layer 100, the shielding region 102, the well regions 104, the source regions 106 and the body contact region 108 are formed of silicon. The drift layer 100 and the source regions 106 have a first conductivity type, the shielding region 102, the well regions 104 and the body contact regions 108 have a second conductivity type different from the first conductivity type. The doping concentration of the source region 106 is higher than the doping concentration of the drift layer 100. The doping concentration of the shielding region 102 and the body contact regions 108 is higher than the doping concentration of the well regions 104. The doping concentration of the source region 106 is higher than the doping concentration of the well regions 104. In some embodiments, the first conductivity type is N type, and the second conductivity type is P type. In some embodiments, the drift layer 100 is formed over a substrate in advance. The conductivity type of the substrate and the drift layer 100 may be the same, and the doping concentration of the substrate may be higher than the doping concentration of the drift layer 100.

The forming sequence of the shielding region 102, the well regions 104, the source regions 106, and the body contact regions 108 may be interchangeable. For example, the shielding region 102 of the second conductivity type may be first formed in the drift layer 100 of the first conductivity type, and there is still a distance between the top of the shielding region 102 and the top of the drift layer 100. Subsequently, the well regions 104 of the second conductivity type are formed at two sides of the shielding region 102. The bottom of the well regions 104 is higher than the top of the shielding region 102 and is not contact with the shielding region 102. Subsequently, the source regions 106 of the first conductivity type are formed at the upper portion of the well regions 104. Subsequently, the body contact regions 108 of the second conductivity type are formed at the upper portion of the well regions 104 and a side of the sources region 106. However, the present disclosure is not limited to the forming sequence mentioned above.

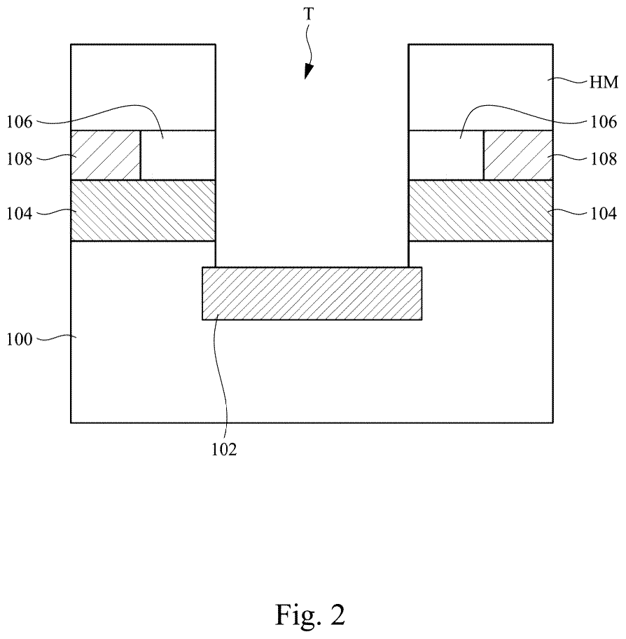

Referring to FIG. 2, a trench T is formed in the drift layer 100, and the trench T exposes the shielding region 102. Specifically, a hard mask layer HM may be first formed over the source regions 106 and the body contact regions 108, and the hard mask layer HM exposes the drift layer 100 over the shielding region 102. Subsequently, an etching process is performed to etch the drift layer 100 over the shielding region 102 to form the trench T, and the bottom of the trench T exposes the shielding region 102. After forming the trench T, the sidewall of the trench T also exposes the source regions 106, the well regions 104 and the drift layer 100.

In the present disclosure, the trench T is formed after forming the shielding region 102. This method can improve the uniformity of the doping concentration of the shielding region 102. Specifically, if the shielding region 102 is formed after forming the trench T, the ion implantation process for forming the shielding region 102 may cause damage to the sidewall of the trench T, or affect the doping concentration of the doped regions at two sides of the trench T. Therefore, a protection layer is formed at the sidewall of the trench T before forming the shielding region 102 to avoid the situation mentioned above. However, this protection layer tends to increase the difficulty of the ion implantation process for forming the shielding region 102, and the uniformity of the doping concentration of the shielding region 102 may be reduced. If the shielding region 102 is formed before forming the trench T, the issue about lower uniformity of the doping concentration of the shielding region 102 due to the existence of the protection layer may be avoided.

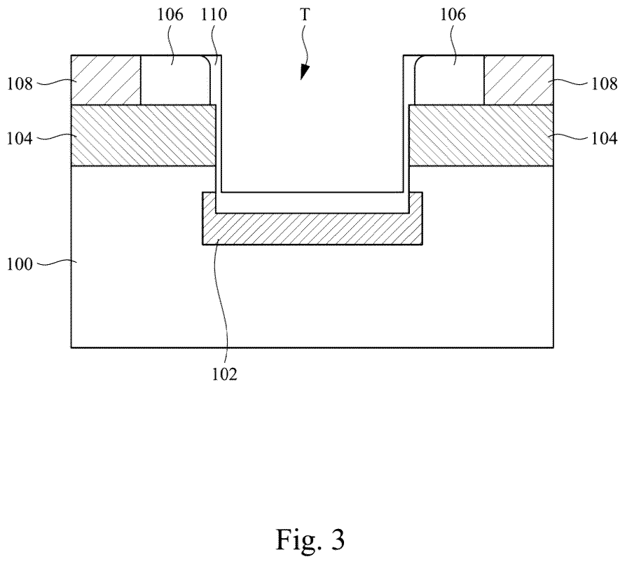

Referring to FIG. 3, the hard mask layer HM is removed after forming the trench T, and a thermal oxidation process is performed to the sidewall and the bottom of the trench T to form a thermal oxidation layer 110 at the sidewall and the bottom of the trench T, in which the thickness of the thermal oxidation layer 110 along the source region 106 is greater than the thickness of the thermal oxidation layer 110 along the well region 104. Specifically, the thermal oxidation process in FIG. 3 smoothens the rough surface caused by the etching process in FIG. 2. The thermal oxidation process has a higher oxidation rate to the region having higher doping concentration, and the doping concentration of the source regions 106 and the shielding region 102 is higher than the doping concentration of the well regions 104. Therefore, the thickness of the thermal oxidation layer 110 along the source region 106 is greater than the thickness of the thermal oxidation layer 110 along the well region 104, and the thickness of the thermal oxidation layer 110 along the shielding region 102 is greater than the thickness of the thermal oxidation layer 110 along the well region 104. Moreover, since the thermal oxidation process oxidizes the top of the source region 106 slower than oxidizes the sidewall of the source region 106, the thermal oxidation layer 110 along the source region 106 has a curved sidewall. In some embodiments, the thermal oxidation layer 110 is a silicon oxide layer. In the present disclosure, since the shielding region 102 is formed before forming the trench T, the ion implantation process for forming the shielding region 102 does not affect the doping concentration of the doped regions at two sides of the trench T easily. That is, the doping concentration of the source regions 106 and the well regions 104 at two sides of the trench T is not affected. Therefore, it is ensured that the thickness of the thermal oxidation layer 110 along the source region 106 is greater than the thickness of the thermal oxidation layer 110 along the well region 104 during the thermal oxidation process. In some embodiments, the thermal oxidation layer 110 is further in contact with the drift layer 100. Since the doping concentration of the source regions 106 is greater than the doping concentration of the drift layer 100, the thickness of the thermal oxidation layer 110 along the source region 106 is greater than the thickness of the thermal oxidation layer 110 along the drift layer 100.

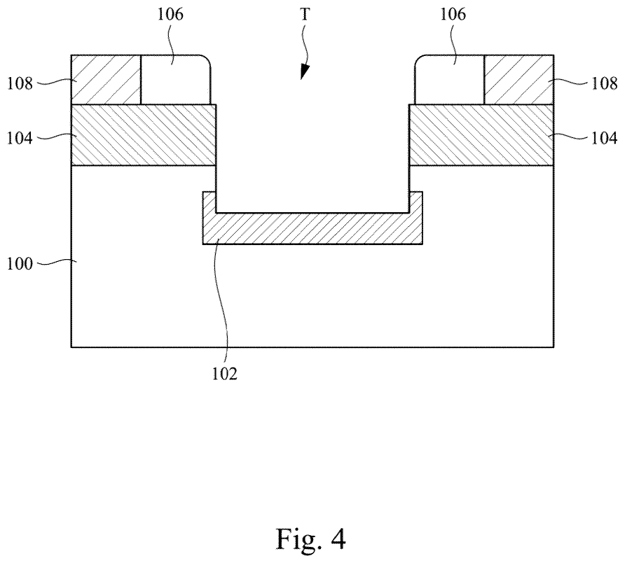

Referring to FIG. 4, the thermal oxidation layer 110 is removed, so the rough surface of the trench T is smoothened. Specifically, a wet etching process is performed to remove the thermal oxidation layer 110 from the surface of the trench T, and portions of the drift layer 100, the shielding region 102, the well regions 104, and the source regions 106 that are not thermally oxidized remain in place. At this time, the top of the trench T is wider than the bottom of the trench T, and the trench T cladded by the source regions 106 is wider than the trench T cladded by the well regions 104. That is, the bottom of the source region 106 is wider than the top of the source region 106. Moreover, the trench T has a curved sidewall at the source region 106.

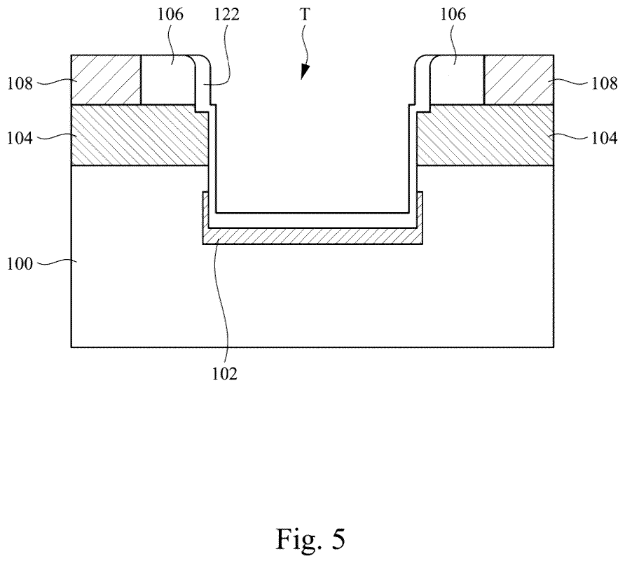

Referring to FIG. 5, a dielectric layer 122 is formed at the sidewall and the bottom of the trench T, in which the thickness of the dielectric layer 122 along the source regions 106 is greater than the thickness of the dielectric layer 122 along the well regions 104. Specifically, the dielectric layer 122 is formed by performing a thermal oxidation process having a higher oxidation rate to the region having higher doping concentration, and the doping concentration of the source regions 106 and the shielding region 102 is higher than the doping concentration of the well regions 104. Therefore, the thickness of the dielectric layer 122 along the source regions 106 is greater than the thickness of the dielectric layer 122 along the well regions 104, and the thickness of the dielectric layer 122 along the shielding region 102 is greater than the thickness of the dielectric layer 122 along the well regions 104. Moreover, since the thermal oxidation process oxidizes the top of the source region 106 slower than oxidizes the sidewall of the source region 106, the dielectric layer 122 along the source region 106 has a curved sidewall. In some embodiments, the dielectric layer 122 is a silicon oxide layer.

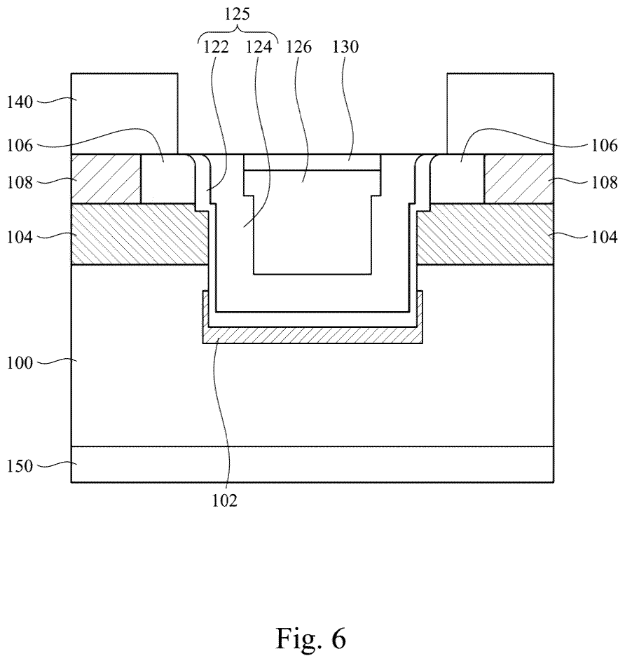

Referring to FIG. 6, a dielectric layer 124 is formed in the trench T. The dielectric layer 124 is a dielectric layer conformal to the profile of the trench T, so the dielectric layer 124 has a substantially uniform thickness. The thickness of the dielectric layer 124 is greater than the thickness of the dielectric layer 122, and after forming the dielectric layer 124, the top of the trench T is still wider than the bottom of the trench T. In some embodiments, the dielectric layer 124 is a silicon oxide layer. In the present disclosure, the dielectric layer 122 and the dielectric layer 124 are collectively referred to as a gate dielectric layer 125. Since the thickness of the dielectric layer 122 along the source regions 106 is greater than the thickness of the dielectric layer 122 along the well regions 104, the thickness of the dielectric layer 122 along the shielding region 102 is greater than the thickness of the dielectric layer 122 along the well regions 104, and the dielectric layer 124 has a substantially uniform thickness, the thickness of the gate dielectric layer 125 along the source regions 106 is greater than the thickness of the gate dielectric layer 125 along the well regions 104, and the thickness of the gate dielectric layer 125 along the shielding region 102 is greater than the thickness of the gate dielectric layer 125 along the well regions 104.

Subsequently, a gate 126 is formed in the trench T. Specifically, the trench T is filled with a conductive material, and a planarization process is performed to remove excess conductive material (such as the conductive material over the source regions 106 and the body contact regions 108) to form the gate 126 in the trench T. Since the top of the trench T is wider than the bottom of the trench T, it is difficult to form voids when filling the conductive material, the top of the resulting gate 126 is also wider than the bottom of the resulting gate 126. The resulting gate 126 also has fewer voids. In some embodiments, the gate 126 may be made of polysilicon, metal or the combinations thereof. Since the bottom of the gate 126 is usually accompanied by a strong electric field, the shielding region 102 and the thick gate dielectric layer 125 at the bottom of the gate 126 may be used to shield the strong electric field. Therefore, the leakage current is less likely to occur.

After forming the gate 126, a dielectric layer 130 may be formed over the gate 126, a source electrode 140 may be formed over the source regions 106 and the body contact regions 108, and a drain electrode 150 may be formed below the drift layer 100. The resulting semiconductor device is illustrated in FIG. 6. The semiconductor device includes a drift layer 100, a gate 126, a gate dielectric layer 125, well regions 104, source regions 106, body contact regions 108, a shielding region 102, a dielectric layer 130, a source electrode 140, and a drain electrode 150. The gate 126 is over the drift layer 100. The gate dielectric layer 125 is along the sidewall and the bottom of the gate 126. The gate dielectric layer 125 is in contact with the source regions 106 and the well regions 104. Each of the well regions 104 are at one of a side of the gate dielectric layer 125. Each of the source regions 106 is at the side of the gate dielectric layer 125 and over one of the well regions 104. The shielding region 102 is at the bottom of the gate dielectric layer 125. Each of the body contact regions 108 is over one of the well regions 104 and is adjacent to one of the source regions 106, and each of the source regions 106 is between one of the body contact regions 108 and the gate dielectric layer 125. The dielectric layer 130 is over the gate 126 and the source regions 106. The source electrode 140 is over the dielectric layer 130, the source regions 106, and the body contact regions 108. The drain electrode 150 is below the drift layer 100.

The thickness of the gate dielectric layer 125 is related to the doping concentration of the regions in contact with the gate dielectric layer 125. If the doping concentration of the regions in contact with the gate dielectric layer 125 is higher, the gate dielectric layer 125 is thicker. Since the doping concentration of the source regions 106 is higher than the doping concentration of the well regions 104, and the doping concentration of the shielding region 102 is higher than the doping concentration of the well regions 104, the thickness of the gate dielectric layer 125 along the source regions 106 is greater than the thickness of the gate dielectric layer 125 along the well regions 104, and the thickness of the gate dielectric layer 125 along the shielding region 102 is greater than the thickness of the gate dielectric layer 125 along the well regions 104. In some embodiments, the gate dielectric layer 125 is further in contact with the drift layer 100, and the doping concentration of the source regions 106 is higher than the doping concentration of the drift layer 100. Therefore, the thickness of the gate dielectric layer 125 along the source regions 106 is greater than the thickness of the gate dielectric layer 125 along the drift layer 100.

As mentioned above, some embodiments of the present disclosure may be used to improve the process of the semiconductor device having the gate trench structure. For example, in the present disclosure, the doped regions of the semiconductor device are formed before the trench is formed. Therefore, the complexity of the ion implantation process in the trench is avoided., and it is ensured that the doping concentration of the doped regions is less likely to be affected. Under this circumstance, the top of the trench becomes wider than the bottom of the trench when the thermal oxidation process is performed to smoothen the surface of the trench. The resulting gate also has fewer voids when the conductive material is filled in the trench.

What is claimed is:

1. A method of manufacturing a semiconductor device, comprising:
forming a shielding region, well region, and a source region in a drift layer, wherein the source region is over the well region, a top of the shielding region is lower than a bottom of the well region, and at least a portion of the shielding region does not overlap the well region;
forming a trench in the drift layer, the trench exposing the shielding region;
forming a gate dielectric layer at a sidewall and a bottom of the trench, wherein a thickness of the gate dielectric layer along the source region is greater than a thickness of the gate dielectric layer along the well region; and
forming a gate in the trench.

2. The method of claim 1, further comprising:
before forming the gate dielectric layer, performing a thermal oxidation process to the sidewall and the bottom of the trench to form a thermal oxidation layer at the sidewall and the bottom of the trench, wherein a thickness of the thermal oxidation layer along the source region is greater than a thickness of the thermal oxidation layer along the well region; and
removing the thermal oxidation layer.

3. The method of claim 2, wherein a thickness of the thermal oxidation layer along the shielding region is greater than the thickness of the thermal oxidation layer along the well region.

4. The method of claim 2, wherein the thermal oxidation process oxidizes a top of the source region slower than oxidizes a sidewall of the source region.

5. The method of claim 2, wherein after removing the thermal oxidation layer, a top of the trench is wider than the bottom of the trench.

6. The method of claim 1, wherein a portion of the gate dielectric layer is formed by performing a thermal oxidation process, and the thermal oxidation process oxidizes a top of the source region slower than oxidizes a sidewall of the source region.

7. The method of claim 1, wherein a thickness of the gate dielectric layer along the shielding region is greater than a thickness of the gate dielectric layer along the well region.

8. The method of claim 1, wherein a doping concentration of the source region is greater than a doping concentration of the well region.

9. The method of claim 1, wherein a doping concentration of the shielding region is greater than a doping concentration of the well region.

10. The method of claim 1, wherein a top of the gate is wider than the bottom of the gate.

11. A semiconductor device, comprising:
a drift layer;
a gate over the drift layer;
a gate dielectric layer along a sidewall and a bottom of the gate;
a shielding region at a bottom of the gate dielectric layer;
a well region at a side of the gate dielectric layer; and
a source region at the side of the gate dielectric layer and over the well region, wherein a thickness of the gate dielectric layer along the source region is greater than a thickness of the gate dielectric layer along the well region.

12. The semiconductor device of claim 11, wherein a thickness of the gate dielectric layer along the shielding region is greater than the thickness of the gate dielectric layer along the well region.

13. The semiconductor device of claim 11, wherein a doping concentration of the shielding region is greater than a doping concentration of the well region.

14. The semiconductor device of claim 11, wherein the gate dielectric layer along the source region has a curved sidewall.

15. The semiconductor device of claim 11, wherein a top of the gate is wider than the bottom of the gate.

16. The semiconductor device of claim 11, wherein a doping concentration of the source region is greater than a doping concentration of the well region.

17. The semiconductor device of claim 11, wherein a conductivity type of the source region is different from a conductivity type of the well region.

18. The semiconductor device of claim 11, wherein a bottom of the source region is wider than a top of the source region.

19. The semiconductor device of claim 11, wherein the gate dielectric layer is in contact with the drift layer, and the thickness of the gate dielectric layer along the source region is greater than a thickness of the gate dielectric layer along the drift layer.

20. The semiconductor device of claim 11, wherein a doping concentration of the source region is greater than a doping concentration of the drift layer.
